(19) United States
(12) Patent Application Publication
(10) Pub. No.: US 2023/0207262 A1
(43) Pub. Date: Jun. 29, 2023

(54) PLASMA GENERATION UNIT, AND APPARATUS FOR TREATING SUBSTRATE WITH THE SAME

(71) Applicant: PSK INC., Gyeonggi-do (KR)

(72) Inventors: Jong Woo Park, Gyeonggi-do (KR); Sung Jin Yoon, Gyeonggi-do (KR); A Ram Kim, Gyeonggi-do (KR); Soo Yeong Yang, Gyeonggi-do (KR); Ji Seung Kim, Gyeonggi-do (KR); Yu Jin Jang, Gyeonggi-do (KR)

(21) Appl. No.: 17/710,269

(22) Filed: Mar. 31, 2022

(30) Foreign Application Priority Data
Dec. 29, 2021 (KR) 1020210190689

(51) Int. Cl. H01J 37/32

(52) U.S. Cl. CPC H01J 37/3211; H01J 37/32651; H01J 37/32522; H01J 2237/327

(57) ABSTRACT

A substrate treating apparatus includes a process treating unit providing a treating space for treating a substrate and a plasma generation unit provided above the process treating unit and generating a plasma from a process gas. The plasma generation unit includes a plasma chamber having a discharge space formed therein, an antenna surrounding an outside of the plasma chamber and flowing a high frequency current therethrough, and a cover member surrounding an outside of the antenna, and wherein the cover member is grounded.

### CROSS-REFERENCE TO RELATED APPLICATION

A claim for priority under 35 U.S.C. § 119 is made to Korean Patent Application No. 10-2021-0190689 filed on Dec. 29, 2021, in the Korean Intellectual Property Office, the entire contents of which are incorporated by reference herein.

### TECHNICAL FIELD

Embodiments of the inventive concept described herein relate to a plasma generation unit and an apparatus for treating a substrate with the same, more specifically, an apparatus for treating the substrate using a plasma.

### BACKGROUND

A plasma refers to an ionized gas state made of ions, radicals, and electrons. The plasma is generated by a very high temperature, strong electric fields, or high frequency RF electromagnetic fields. The semiconductor device manufacturing process includes an ashing process or an etching process of removing a thin film on the substrate using the plasma. The ashing process or the etching process is performed by colliding or reacting ions and radical particles contained in the plasma with the film on the substrate.

An antenna wound with a plurality of coils is provided in the plasma source generating the plasma. The antenna includes an input terminal to which a high frequency power is applied and an end terminal which is grounded. The input terminal of the antenna has a relatively stronger magnitude of high frequency power than the end terminal of the antenna. Accordingly, an intensity of a generated electromagnetic field between a region adjacent to the input terminal of the antenna and a region adjacent to the end terminal of the antenna is different. Accordingly, a plasma generated in the plasma chamber is asymmetrically formed. This causes an asymmetry of the plasma working on the substrate and acts as a factor that hinders a process uniformity of substrate treatment.

### SUMMARY

Embodiments of the inventive concept provide a plasma generation unit and a substrate treating apparatus with the same for effectively performing a plasma treatment on a substrate.

Embodiments of the inventive concept provide a plasma generation unit and a substrate treating apparatus with the same for minimizing an asymmetry of a plasma.

Embodiments of the inventive concept provide a plasma generation unit and a substrate treating apparatus with the same for minimizing an influence of an electromagnetic field generating at an antenna on an outer structure of a plasma chamber.

Embodiments of the inventive concept provide a plasma generation unit and a substrate treating apparatus with the same for minimizing a heating of a plasma chamber due to a generation of a plasma.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a process treating unit providing a treating space for treating a substrate; and a plasma generation unit provided above the process treating unit and generating a plasma from a process gas, and wherein the plasma generation unit comprises: a plasma chamber having a discharge space formed therein; an antenna surrounding an outside of the plasma chamber and flowing a high frequency current therethrough; and a cover member surrounding an outside of the antenna, and wherein the cover member is grounded.

In an embodiment, the cover member has a slot extending from a top end of the cover member to a bottom end of the cover member.

In an embodiment, the slot is provided in a plurality, and the plurality of slots are placed apart from one another in a direction surrounding the antenna.

In an embodiment, a length of a lengthwise direction of the cover member is the same or longer than a length of a lengthwise direction of the antenna.

In an embodiment, the plasma generation unit further comprises a fan unit supplying an airflow to a space between the cover member and the plasma chamber.

In an embodiment, the fan unit is installed at the cover member, and in a position not overlapping with the slot.

In an embodiment, the antenna comprises a coil part surrounding an outside of the plasma chamber in a plurality of turns, and the coil part has a ground terminal to be grounded and a power terminal to be supplied with a high frequency power.

In an embodiment, the coil part comprises a plurality of coils, and each of the plurality of coils are independently connected to the power terminal and the ground terminal.

In an embodiment, the plasma generation unit further comprises a shield member positioned between the antenna and the plasma chamber, and grounded.

In an embodiment, the cover member has a disk shape when seen from above.

In an embodiment, the cover member has a polygonal shape when seen from above.

The inventive concept provides a plasma generation unit provided in a substrate treating apparatus using a plasma. The plasma generation unit includes a chamber having a discharge space formed therein; an antenna surrounding an outside of the chamber and flowing a high frequency current flowing therethrough; and a cover member surrounding an outside of the antenna, and wherein the cover member is grounded to generate an induced current in a opposite direction of the high frequency current.

In an embodiment, the cover member has a slot extending along a lengthwise direction of the shield member.

In an embodiment, the slot is provided in a plurality, and the plurality of slots are placed apart from one another in a direction surrounding the antenna.

In an embodiment, the plasma generation unit further includes a fan unit supplying an airflow to a space between the cover member and the chamber to cool the chamber.

In an embodiment, the antenna comprises a coil part surrounding the outside of the plasma chamber a plural number of times, and the coil part has a ground terminal to be grounded and a power terminal to be supplied with a high frequency power.

In an embodiment, the coil part comprises a plurality of coils, and each of the plurality of coils are independently connected to the power terminal and the ground terminal.

In an embodiment, a length of a lengthwise direction of the cover member is the same or longer than a length of a lengthwise direction of the antenna.

In an embodiment, the cover member has a polygonal shape when seen from above.

The inventive concept provides a substrate treating apparatus. The substrate treating apparatus includes a process treating unit for treating a substrate; and a plasma generation unit positioned above the process treating unit for generating a plasma by exciting a gas, and wherein the process treating unit comprises: a housing having a treating space; and a support unit placed in the treating space and supporting a substrate, and wherein the plasma generation unit comprises: a plasma chamber having a discharge space formed therein; an antenna surrounding an outside of the plasma chamber and flowing a high frequency current flowing therethrough; and a cover member surrounding an outside of the antenna and grounded, and wherein the cover member has at least one slot extending from a top end of the cover member to a bottom end of the cover member.

According to an embodiment of the inventive concept, a plasma treatment for effectively treating a substrate may be performed.

According to an embodiment of the inventive concept, an asymmetry of a plasma may be minimized.

According to an embodiment of the inventive concept, an electromagnetic field generated at an antenna affecting an outer structure of a plasma chamber may be minimized.

According to an embodiment of the inventive concept, a heating of a plasma chamber due to a generation of a plasma may be minimized.

The effects of the inventive concept are not limited to the above-mentioned ones, and the other unmentioned effects will become apparent to those skilled in the art from the following description.

### BRIEF DESCRIPTION OF THE DRAWINGS

The above and other objects and features will become apparent from the following description with reference to the following figures, wherein like reference numerals refer to like parts throughout the various figures unless otherwise specified, and wherein:

FIG. 1 is a view schematically illustrating a substrate treating apparatus according to an embodiment of the inventive concept.

FIG. 2 is a view schematically illustrating an embodiment of a process chamber performing a plasma treating process in the process chamber of the substrate treating apparatus of FIG. 1.

FIG. 3 is a view schematically illustrating a top view of a cover member according to an embodiment of FIG. 2.

FIG. 4 is a perspective view of a cover member according to an embodiment of FIG. 2.

FIG. 5 is a view schematically illustrating a state in which a current flows in an antenna and a cover member according to an embodiment of FIG. 2.

FIG. 6 is a top view of a plasma formed inside the process chamber of FIG. 2.

FIG. 7 is a perspective view of a cover member according to another embodiment of FIG. 2.

FIG. 8 through FIG. 10 are views schematically showing a top view of a cover member according to another embodiment of FIG. 2.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

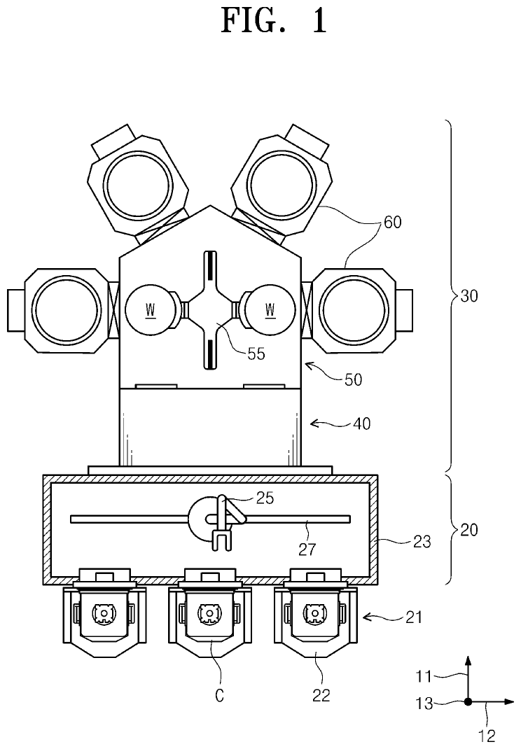

Hereinafter, an embodiment of the inventive concept will be described in detail with reference to FIG. 1 through FIG. 10.

FIG. 1 is a view schematically illustrating a substrate treating apparatus according to an embodiment of the inventive concept. Referring to FIG. 1, the substrate treating apparatus 1 includes an equipment front end module EFFM 20 and a treating module 30. The equipment front end module 20 and the treating module 30 are disposed in a row. Hereinafter, a direction in which the equipment front end module 20 and the treating module 30 are arranged is defined as a first direction 11. In addition, a direction perpendicular to the first direction 11 is defined as a second direction 12, and a direction perpendicular to both the first direction 11 and the second direction 12 is defined as a third direction 13.

The equipment front end module 20 has a load port 21 and a transfer frame 23. The load port 21 is disposed in front of the equipment front end module 20 in the first direction 11. The load port 21 has a support unit 22. A plurality of support units 22 may be provided. Each of the support units 22 may be arranged in a row in the second direction 12. In the support unit 22, a carrier C (e.g., cassette, FOUP, etc.) is seated in which the substrate W to be provided in the process and the substrate W on which the treating is completed are stored.

The transfer frame 23 is disposed between the load port 21 and the treating module 30. The transfer frame 23 may have an inner space. The load port 21 and a first transfer robot 25 may be disposed in the inner space of the transfer frame 23. The first transfer robot 25 may transfer the substrate W between the load port 21 and the treating module 30. The first transfer robot 25 may move along the transfer rail 27 provided in the second direction 12 to transfer the substrate W between the carrier C and the treating module 30.

The treating module 30 may include a load lock chamber 40, a transfer chamber 50, and a process chamber 60.

The load lock chamber 40 is disposed adjacent to the transfer frame 23. For example, the load lock chamber 40 may be disposed between the transfer chamber 50 and the equipment front end module 20. The load lock chamber 40 provides a space for standby before the substrate W to be provided in the process is transferred to the process chamber 60 or before the substrate W on which the treating is completed is transferred to the equipment front end module 20.

The transfer chamber 50 is disposed adjacent to the load lock chamber 40. The transfer chamber 50 may have a polygonal body when viewed from above. For example, the transfer chamber 50 may have a pentagonal body when viewed from above. Outside the body, the load lock chamber 40 and a plurality of process chambers 60 may be disposed along a circumference of the body. A passage (not shown) through which the substrate W enters and exits may be formed on each sidewall of the body. The passage (not shown) may connect the transfer chamber 50 to the load lock chamber 40 or the process chambers 60. A door (not shown) for opening and closing a passage (not shown) to seal an inside thereof may be provided in each passage (not shown).

A second transfer robot 55 for transferring the substrate W between the load lock chamber 40 and the process chambers 60 is disposed in an inner space of the transfer chamber 50. The second transfer robot 55 may transfer an untreated substrate W standing by in the load lock chamber 40 to the process chamber 60. The second transfer robot 55 may transfer the substrate W on which the treating has been completed to the load lock chamber 40. In addition, the second transfer robot 55 may transfer the substrate W between the process chambers 60 to sequentially provide the substrate W to a plurality of process chambers 60.

In an embodiment, when the transfer chamber 50 has a pentagonal body as shown in FIG. 1, load lock chambers 40 may each be disposed on sidewalls adjacent to the equipment front end module 20, and the process chambers 60 may be sequentially disposed on the other sidewalls. However, this invention is not limited to the aforementioned examples, and a shape of the transfer chamber 60 is not limited thereto, and can be modified and provided in various forms depending on the required process module.

The process chamber 60 is disposed along a circumference of the transfer chamber 50. A plurality of process chambers 60 may be provided. In each process chamber 60, a process treatment on the substrate W is performed. The process chamber 60 receives and processes the substrate W from the second transfer robot 55, and provides the substrate Won which the process treating is completed to the second transfer robot 55.

The process treatment performed in each process chamber 60 may be different from each other. A process performed by the process chamber 60 may be one of the processes of producing a semiconductor device or a display panel using the substrate W. The substrate W treated by the substrate treating apparatus 1 is a comprehensive concept including all of a semiconductor device, a flat panel display (FPD), and other substrates W used in manufacturing an object on which a thin film circuit pattern is formed. For example, the substrate W may be a silicon wafer, a glass substrate, or an organic substrate.

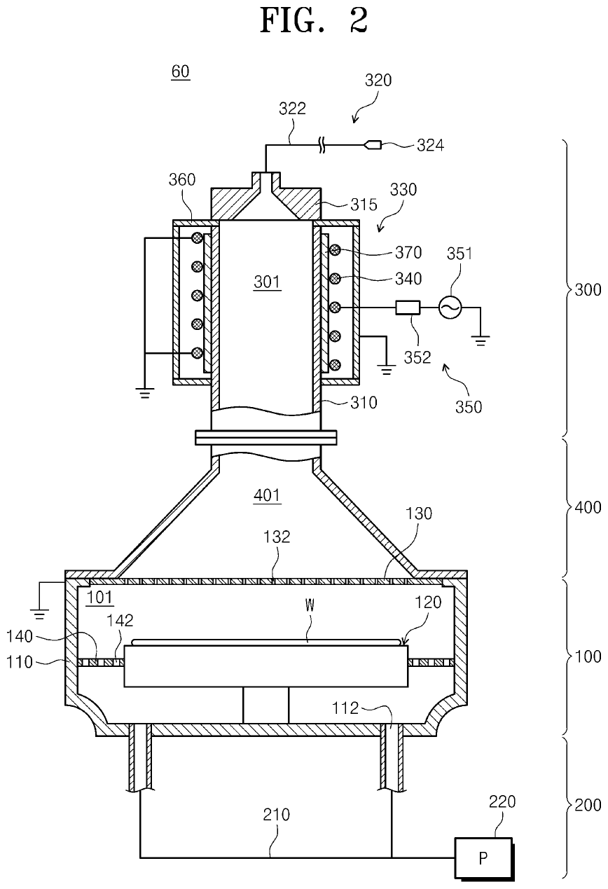

FIG. 2 is a view schematically illustrating an embodiment of a process chamber performing a plasma process treatment in the process chamber of the substrate treating apparatus of FIG. 1. Hereinafter, a process of treating the substrate W using a plasma in the process chamber 60 will be described as an example.

Referring to FIG. 2, the process chamber 60 may perform a predetermined process on the substrate W using a plasma. For example, the process chamber 60 may etch or ash a thin film on the substrate W. The thin film may be various types of films such as a polysilicon film, an oxide film, or a silicon nitride film. Optionally, the thin film may be a natural oxide film or an oxide film produced by a chemical action.

The process chamber 60 may include a process treating unit 100, an exhaust unit 200, a plasma generation unit 300, and a diffusion unit 400.

The process treating unit 100 provides a treating space 101 in which the substrate W is placed and the treating of the substrate W is performed. The plasma generation unit 300 to be described later discharges a process gas to generate the plasma, and supplies the generated plasma to the treating space 101 of the process treating unit 100. The process gas and/or reaction by-products generated in the process of treating the substrate W remaining inside the process treating unit 100 are discharged to the outside of the process chamber 60 through an exhaust unit 200 to be described later. Accordingly, an internal pressure of the process treating unit 100 may be maintained as a set pressure.

The process treating unit 100 may include a housing 110, a support unit 120, a baffle 130, and an exhaust baffle 140.

The housing 110 has a treating space in which the substrate W is treated. An outer wall of the housing 110 may be provided as a conductor. In an embodiment, the outer wall of the housing 110 may be made of a metal material including aluminum. According to an embodiment, the housing 110 may be grounded. A top portion of the housing 110 may be opened. The open top portion of the housing 110 may be connected to a diffusion chamber 410 to be described later. An opening (not shown) may be formed on a sidewall of the housing 110. The opening (not shown) may be opened and closed by an opening and closing member such as a door (not shown). The substrate W enters and exits the housing 110 through an opening (not shown) formed on the sidewall of the housing 110.

In addition, an exhaust hole 112 may be formed on a bottom surface of the housing 110. The exhaust hole 112 may exhaust the process gas and/or by-products flowing through the treating space 101 to the outside of the treating space 101. The exhaust hole 112 may be connected to components included in the exhaust unit 200 to be described later.

The support unit 120 is located inside the treating space 101. The support unit 120 supports the substrate Win the treating space 101. The support unit 120 may include a support plate 122 and a support shaft 124.

The support plate 122 may fix and/or support an object. The support plate 122 may fix and/or support the substrate W. When viewed from above, the support plate 122 may be provided in a substantially disk shape. The support plate 122 is supported by the support shaft 124. The support plate 122 may be connected to an external power source (not shown). The support plate 122 may generate a static electricity by a power applied from an external power source (not shown). An electrostatic force of the generated static electricity may fix the substrate W to a top surface of the support plate 122. However, this invention is not limited thereto, and the support plate 122 may fix and/or support the substrate W in a physical method such as a mechanical clamp or a vacuum sucking method.

The support shaft 124 may move the object. The support shaft 124 may move the substrate W in an up/down direction. For example, the support shaft 124 may be coupled to the support plate 122 and may move the substrate W seated on the top surface of the support plate 122 up and down by raising and lowering the support plate 122.

The baffle 130 may uniformly transfer the plasma generated in the plasma generation unit 300 to be described later to the treating space 101. The baffle 130 may uniformly distribute the plasma generated by the plasma generation unit 300 and flowing inside the diffusion unit 400 to the treating space 101.

The baffle 130 may be disposed between the process treating unit 100 and the plasma generation unit 300. The baffle 130 may be disposed between the support unit 120 and the diffusion unit 400. For example, the baffle 130 may be disposed above the support plate 122

The baffle 130 may have a plate shape. When viewed from above, the baffle 130 may have a substantially disk shape. When viewed from above, the baffle 130 may be disposed to overlap the top surface of the support plate 122.

A baffle hole 132 is formed in the baffle 130. A plurality of baffle holes 132 may be provided. The baffle holes 132 may be provided to be spaced apart from each other. For example, the baffle holes 132 may be formed to be spaced apart from each other by a predetermined interval on a circumference of a concentric center of the baffle 130 to supply a uniform plasma (or radical). A plurality of baffle holes 132 may penetrate from a top end to a bottom end of the baffle 130. A plurality of baffle holes 132 may function as a passage through which the plasma generated in the plasma generation unit 330 flows to the treating space 101.

A surface of the baffle 130 may be made of an oxidized aluminum material. The baffle 130 may be electrically connected to a top wall of the housing 110. Optionally, the baffle 130 may be independently grounded. As the baffle 130 is grounded, ions included in the plasma passing through the baffle hole 132 may be captured. For example, charged particles such as electrons or ions included in the plasma may be trapped in the baffle 130, and neutral particles without charge, such as radicals included in the plasma, may pass through the baffle hole 132 and be supplied to the treating space 101.

The baffle 130 in accordance with an embodiment of this invention described above has been described as an example provided in a disk shape with a thickness, but is not limited thereto. For example, the baffle 130 may have a generally circular shape when viewed from above, but may have a shape in which a height of the top surface thereof increases from an edge region toward a center region when viewed from a cross-section. In an embodiment, when viewed from a cross section, the baffle 130 may have a shape in which the top surface thereof is upwardly inclined from the edge region toward the center region. Accordingly, the plasma generated from the plasma generation unit 330 may flow to the edge region of the treating space 101 along an inclined cross section of the baffle 130.

The exhaust baffle 140 uniformly exhausts the plasma flowing in the treating space 101 for each region. In addition, the exhaust baffle 140 may adjust a residual time of the plasma flowing in the treating space 101. The exhaust baffle 140 has an annular ring shape when viewed from above. The exhaust baffle 140 may be located between an inner wall of the housing 110 and the support unit 120 in the treating space 101.

A plurality of exhaust holes 142 are formed in the exhaust baffle 140. A plurality of exhaust holes 142 are provided as through holes penetrating a top surface and a bottom surface of the exhaust baffle 140. The exhaust holes 142 may be provided to face the up/down direction. The exhaust holes 142 are arranged to be spaced apart from each other along a circumferential direction of the exhaust baffle 140. The reaction by-products passing through the exhaust baffle 140 are discharged to the outside of the process chamber 60 through the exhaust hole 112 formed in a bottom surface of the housing 110 and an exhaust line 210 to be described later.

The exhaust unit 200 exhausts impurities such as the process gas and/or process by-products of the treating space 101 to the outside. The exhaust unit 200 may exhaust impurities and particles generated in the process of treating the substrate W to the outside of the process chamber 60. The exhaust unit 200 may include an exhaust line 210 and a decompression member 220.

The exhaust line 210 functions as a passage through which reaction by-products remaining in the treating space 101 are discharged to the outside of the process chamber 60. An end of the exhaust line 210 communicates with the exhaust hole 112 formed on the bottom surface of the housing 110. Another end of the exhaust line 210 is connected to the decompression member 220 that provides a negative pressure.

The decompression member 220 provides the negative pressure to the treating space 101. The decompression member 220 may discharge process by-products, a process gas, a plasma, or the like remaining in the treating space 101 to the outside of the housing 110. In addition, the decompression member 220 may adjust a pressure of the treating space 101 so that the pressure of the treating space 101 is maintained at a preset pressure. The decompression member 220 may be provided as a pump. However, the inventive concept is not limited thereto, and the decompression member 220 may be variously modified and provided as a known device for providing the negative pressure.

The plasma generation unit 300 may be located above the process treating unit 100. In addition, the plasma generation unit 300 may be located above the diffusion unit 400 to be described later. The process treating unit 100, the diffusion unit 400, and the plasma generation unit 300 may be sequentially disposed from the ground along the third direction 13. The plasma generation unit 300 may be separated from the housing 110 and the diffusion unit 400. A sealing member (not shown) may be provided at a position where the plasma generation unit 300 and the diffusion unit 400 are coupled.

The plasma generation unit 300 may include a plasma chamber 310, a gas supply unit 320, and a plasma generation unit 330.

The plasma chamber 310 has a discharge space 301 therein. The discharge space 301 functions as a space for forming the plasma by exciting the process gas supplied from the gas supply unit 320 to be described later. The plasma chamber 310 may have a shape in which a top surface and a bottom surface are opened. In an embodiment, the plasma chamber 310 may have a cylindrical shape with an open top surface and an open bottom surface. The plasma chamber 310 may be made of a ceramic material or a material including aluminum oxide Al2O3. A top end of the plasma chamber 310 is sealed by a gas supply port 315. The gas supply port 315 is connected to a gas supply pipe 322 to be described later. A bottom end of the plasma chamber 310 may be connected to a top end of the diffusion chamber 410 to be described later.

The gas supply unit 320 supplies the process gas to the gas supply port 315. The gas supply unit 320 supplies the process gas to the discharge space 301 through the gas supply port 315. The process gas supplied to the discharge space 301 may be uniformly distributed to the treating space 101 through the diffusion space 401 and the baffle hole 132 to be described later.

The gas supply unit 320 may include a gas supply pipe 322 and a gas supply source 324. An end of the gas supply pipe 322 is connected to the gas supply port 315, and another end of the gas supply pipe 322 is connected to the gas supply source 324. The gas supply source 324 functions as a source for storing and/or supplying the process gas. The process gas stored and/or supplied by the gas supply source 324 may be a gas for a plasma generation. For example, the process gas may include a difluoromethane CH2F2, a nitrogen N2, and/or an oxygen O2. Optionally, the process gas may further include a tetrafluoromethane CF4, a fluorine, and/or a hydrogen.

The plasma generation unit 330 generates the plasma in the discharge space 301 by exciting the process gas supplied from the gas supply unit 320. The plasma generation unit 330 excites the process gas supplied to the discharge space 301 by applying a high frequency power to the discharge space 301. The plasma generation unit 330 may include an antenna 340, a power module 350, a cover member 360, and a shield member 370. The antenna 340 and the power module 350 may function as plasma sources for generating the plasma in the discharge space 301.

The antenna 340 may be an inductively coupled plasma ICP antenna. The antenna 340 may include a coil part 342 that winds the plasma chamber 310 a plurality of times outside the plasma chamber 310. The coil part 342 may surround an outside of the plasma chamber 310. The coil part 342 may spiral-wind the outside of the plasma chamber 310 a plurality of times. The coil part 342 may be wound around the plasma chamber 310 in a region corresponding to the discharge space 301.

For example, the coil part 342 may have a length in the up/down direction corresponding to a top end to the bottom end of the plasma chamber 310. For example, an end of the coil part 342 may be provided at a height corresponding to a top region of the plasma chamber 310 when viewed from a front end surface of the plasma chamber 310. In addition, another end of the coil part 342 may be provided at a height corresponding to a bottom region of the plasma chamber 310 when viewed from the front end surface of the plasma chamber 310.

A power terminal 345 and a ground terminal 346 may be formed in the coil part 342. A power source 351 to be described later may be connected to the power terminal 345. The high frequency power supplied from the power source 351 may be applied to the coil part 342 through the power terminal 345. The ground terminal 346 may be connected to a ground line. The ground terminal 346 may ground the coil part 342. Although not shown, a capacitor (not shown) may be installed on a ground line connected to the ground terminal 346. The capacitor (not shown) installed on the ground line may be a variable device. A capacitor (not shown) installed on the ground line may be provided as a variable capacitor having a changed capacity. Optionally, a capacitor (not shown) installed on the ground line may be provided as a fixed capacitor with a fixed capacity.

The power terminal 345 may be formed at a point corresponding to ½ of the total length of the coil part 342. In addition, the ground terminal 346 may be formed at an end and at another end of the coil part 342. However, the inventive concept is not limited thereto, and the power terminal 345 and the ground terminal 346 may be formed by being changed to various positions of the coil part 342. For example, the power terminal 345 formed in the coil part 342 may be formed at an end of the coil part 342, and the ground terminal 346 formed in the coil part 342 may be formed at another end of the coil part 342.

In the above-described example, for convenience of description, the coil part 342 surrounds the outside of the plasma chamber 310 with a single coil, and the power terminal 345 and the ground terminal 346 are formed in the coil part 342, but this invention is not limited thereto.

For example, the coil part 342 according to an embodiment of the inventive concept may include a first coil part 343 and a second coil part 344. Each of the first coil part 343 and the second coil part 344 may be provided to surround the outside of the plasma chamber 310 in a spiral shape. The first coil part 343 and the second coil part 344 may be provided to cross and surround the outside of the plasma chamber 310. In addition, the power terminal 345 and the ground terminal 346 may be independently formed in the first coil part 343 and the second coil part 344, respectively. The magnitudes of the high frequency power applied to the first coil part 343 and the second coil part 344 may be different. Accordingly, plasma sizes generated in one region of the plasma chamber 310 adjacent to the first coil part 343 and another region of the plasma chamber 310 adjacent to the second coil part 344 may be provided differently.

The power module 350 may include a power supply 351, a power switch (not shown), and a matcher 352. The power supply 351 applies a power to the antenna 340. The power supply 351 may apply the high frequency power to the antenna 340. The power may be applied to the antenna 340 according to on/off of the power switch (not shown). The high frequency power applied to the antenna 340 generates a high frequency current in the coil part 342. The high frequency current applied to the antenna 340 may form an induced electric field in the discharge space 301. The process gas supplied to the discharge space 301 may be excited in a plasma state by obtaining an energy required for ionization from the induced electric field.

The matcher 352 may perform a matching on the high frequency power applied from the power source 351 to the antenna 340. The matcher 352 may be connected to the output terminal of the power source 351 to match an output impedance and an input impedance of the power source 351.

Although the power module 350 according to an embodiment of the inventive concept described above includes a power source 351, a power switch (not shown), and a matcher 352, the inventive concept is not limited thereto. The power module 350 according to an embodiment of the inventive concept may further include a capacitor (not shown). The capacitor (not shown) may be a variable device. The capacitor (not shown) may be provided as a variable capacitor whose capacity is changed. Optionally, the capacitor (not shown) may be provided as a fixed capacitor with a fixed capacity.

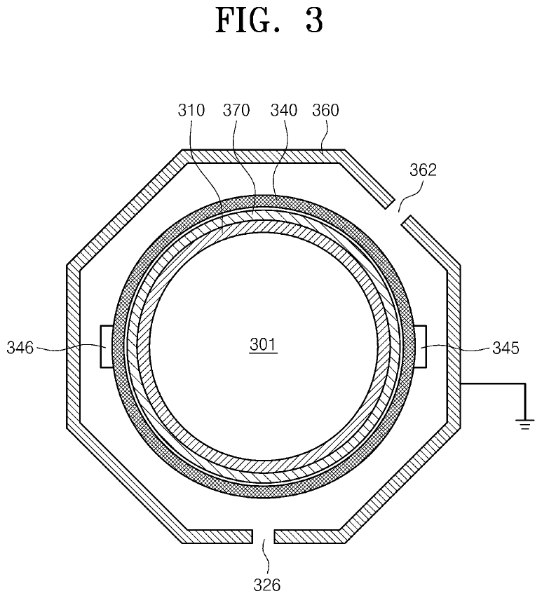

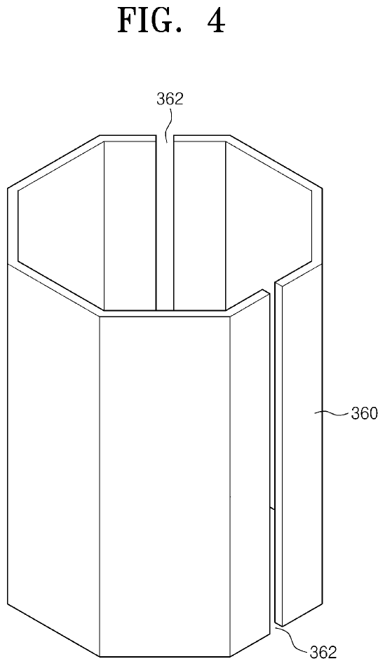

FIG. 3 is a view schematically illustrating a top view of a cover member according to an embodiment of FIG. 2. FIG. 4 is a perspective view of a cover member according to an embodiment of FIG. 2.

Hereinafter, a cover member according to an embodiment of the inventive concept will be described in detail with reference to FIG. 2 through FIG. 4. Referring to FIG. 2 through 4, the cover member 360 may be disposed outside the plasma chamber 310. The cover member 360 may be formed to surround the outside of the antenna 340. A length of the cover member 360 in a vertical direction may correspond to a length of the antenna 340 in the vertical direction. Optionally, a length from a top end to a bottom end of the cover member 360 may be provided to be greater than a length from a top end to a bottom end of the antenna 340. For example, the top end of the cover member 360 may be positioned above a top end of the antenna 340. In addition, the bottom end of the cover member 360 may be located below the bottom end of the antenna 340.

The cover member 360 may be formed of a metal material. The cover member 360 is grounded. As the cover member 360 is grounded, an induced current may be formed in the cover member 360 in a direction opposite (e.g., counterclockwise) to a direction of a high frequency current flowing from the antenna 340 (e.g., clockwise). Accordingly, the electromagnetic field generated from the high frequency current flowing from the antenna 340 by the cover member 360 may be prevented from flowing out of the cover member 360. For example, the electromagnetic field generated by the antenna 340 flows only into the discharge space 301 inside the plasma chamber 310 and does not flow out of the cover member 360. Accordingly, it is possible to minimize a damage to components present outside the cover member 360 and of the substrate treating apparatus 1 by an electromagnetic field.

The cover member 360 may have a polygonal shape. In an embodiment, the cover member 360 may have an octagonal shape when viewed from a front cross-section. A slot 362 is formed on a sidewall of the cover member 360. The slot 362 may be formed in a direction where a lengthwise direction from a sidewall of the cover member 360 corresponds to a direction corresponding to a lengthwise direction of the cover member 360. For example, the slot 362 may be formed in the up/down direction. The slot 362 may extend from a top end to a bottom end of the cover member 360.

At least one slot 362 may be formed. For example, a plurality of slots 362 may be formed on a sidewall of the cover member 360. For example, as shown in FIG. 3, two slots 362 may be formed on the sidewall of the cover member 360. Unlike FIG. 3, according to a need for a process, the slot 362 may be formed with three or more integers on a sidewall of the cover member 360. The plurality of slots 362 may be disposed to be spaced apart from each other in a circumferential direction of the cover member 360. For example, the plurality of slots 362 may be disposed to be spaced apart from each other in a direction surrounding the antenna 340.

Referring back to FIG. 2, the shield member 370 may be provided as a Faraday shield. The shield member 370 may be installed outside the plasma chamber 310. The shield member 370 may be positioned between the plasma chamber 310 and the antenna 340. The shield member 370 may be installed on an outer wall of the plasma chamber 310. The shield member 370 may be formed in a ring shape. A length of the shield member 370 in the up/down direction may be the same as the length of the antenna 340 or may be greater than the length of the antenna 340 in the up/down direction. The shield member 370 may be grounded. The shield member 370 may be made of a material including a metal. The shield member 370 may minimize a direct exposure of the high frequency power applied to the antenna 340 to the plasma generated in the discharge space 301.

The diffusion unit 400 may diffuse the plasma generated by the plasma generation unit 300 into the treating space 101. The diffusion unit 400 may include a diffusion chamber 410. The diffusion chamber 410 has a diffusion space 401 therein. The diffusion space 401 may diffuse the plasma generated in the discharge space 301. The diffusion space 401 connects the treating space 101 and the discharge space 301 to each other and functions as a passage through which the plasma generated in the discharge space 301 flows to the treating space 101.

The diffusion chamber 410 may be generally provided in an inverted funnel shape. The diffusion chamber 410 may have a shape in which a diameter increases from a top end to a bottom end. An inner circumferential surface of the diffusion chamber 410 may be formed of a non-conductor. For example, the inner circumferential surface of the diffusion chamber 410 may be made of a material including a quartz.

The diffusion chamber 410 is positioned between the housing 110 and the plasma chamber 310. The top end of the diffusion chamber 410 may be connected to the bottom end of the plasma chamber 310. A sealing member (not shown) may be provided between the top end of the diffusion chamber 410 and the bottom end of the plasma chamber 310.

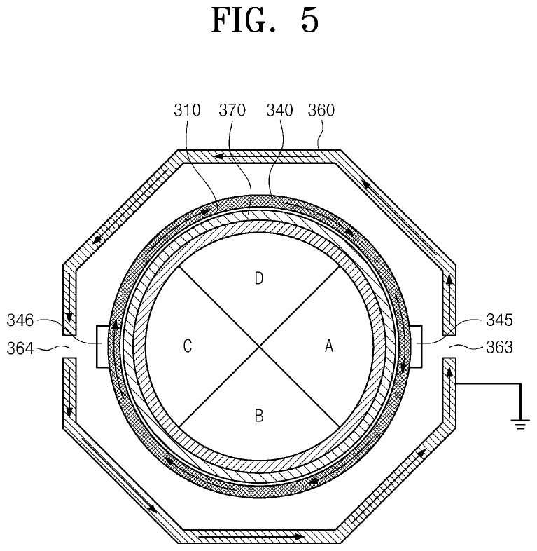

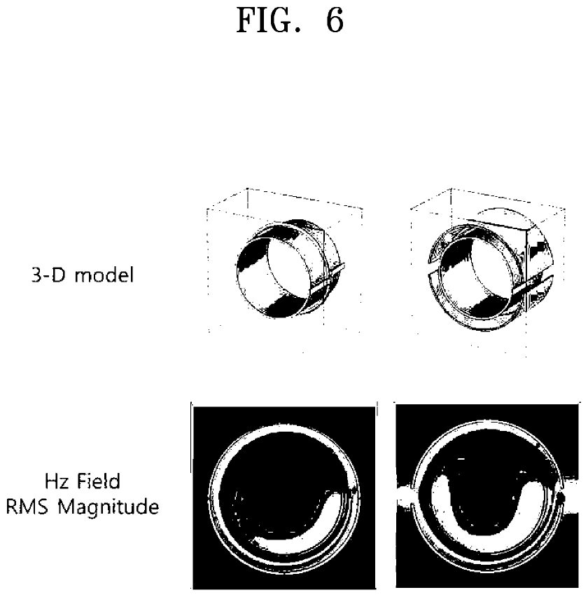

FIG. 5 is a view schematically illustrating a state in which a current flows in the antenna and the cover member according to an embodiment of FIG. 2. FIG. 6 is a top view of the plasma formed inside the process chamber of FIG. 2. Hereinafter, a flow of the plasma generated in the plasma chamber according to a flow of the current of the cover member and the antenna according to an embodiment of the inventive concept will be described in detail with reference to FIG. 5 and FIG. 6.

Hereinafter, for convenience of description, a first slot 363 and a second slot 364 are formed in the cover member 360, the first slot 363 is disposed at a position adjacent to the power terminal 345, and the second slot 364 is disposed at a position adjacent to the ground terminal 346. In addition, a region in the discharge space 301 adjacent to a region where the first slot 363 is formed is defined as region A, and the discharge space 301 is sequentially divided from region A in a clockwise direction into region B, region C, and region D.

Referring to FIG. 5, the high frequency current from the high frequency power supplied from the power source 351 flows through the antenna 340. For example, as shown in FIG. 5, the high frequency current flowing through the antenna 340 may flow in the clockwise direction. In addition, since the cover member 360 is grounded, the induced current flows inside the cover member 360 in a direction opposite to the high frequency current flowing through the antenna 340. For example, as shown in FIG. 5, the induced current flows in a counterclockwise direction inside the cover member 360.

The induced current formed in the cover member 360 may not flow in a portion in which the slot 362 is formed. Accordingly, since an interference does not occur in the high frequency current flowing through the antenna 340 due to the induced current of the cover member 360 at the part in which the slot 362 is formed, an intensity of the electromagnetic field generated from the antenna 340 in which the slot 362 is formed to the discharge space 301 may be relatively strong compared to an intensity of the electromagnetic field generated from the antenna 340 in which the slot 362 is not formed. For example, an intensity of the electromagnetic field generated by the antenna 340 corresponding to a portion where the first slot 363 is formed is relatively stronger than an intensity of the electromagnetic field generated by the antenna 340 corresponding to a portion in which the slot 362 is not formed.

For example, as shown in FIG. 5 and FIG. 6, an intensity of an electromagnetic field generated in region A of the discharge space 301 corresponding to a portion in which the first slot 363 is formed is relatively stronger than an intensity of an electromagnetic field generated in region B and region D of the discharge space 301 in which the slot 362 is not formed. Accordingly, a density of a plasma generated in region A of the discharge space 301 adjacent to a portion where the first slot 363 is formed is relatively higher than a density of a plasma generated in region B and region D.

In addition, as shown in FIG. 5 and FIG. 6, an intensity of the electromagnetic field generated in region C of the discharge space 301 corresponding to the part where the second slot 364 is formed is relatively stronger than an intensity of the electromagnetic field generated in region B and region D of the discharge space 301 in which the slot 362 is not formed. Accordingly, a density of a plasma generated in region C of the discharge space 301 adjacent to the part where the second slot 364 is formed is relatively higher than a density of a plasma generated in region B and region D.

In general, the antenna 340 is provided with an input terminal (e.g., a power terminal 345) to which the high frequency power is applied and an end terminal (e.g., a ground terminal 346) to be grounded. The input terminal of the antenna 340 has a relatively stronger magnitude of the high frequency power than the end terminal of the antenna 340. Accordingly, an intensity of the electromagnetic field acting on the discharge space 301 adjacent to the input terminal of the antenna 340 is relatively stronger than an intensity of the electromagnetic field acting on the discharge space 301 adjacent to the end terminal of the antenna 340. Accordingly, a difference in the intensity of plasma occurs in the discharge space 301. This leads to the plasma acting in different sizes on the substrate W, and acts as a factor that hinders a uniformity of the substrate treating process.

According to the above-described embodiment of the inventive concept, the electromagnetic field generated from the high frequency current flowing from the antenna 340 due to the cover member 360 may be prevented from flowing out of the cover member 360. Furthermore, by forming the slot 362 in the cover member 360, the intensity of the electromagnetic field generated in a region adjacent to the part in which the slot 362 is formed and a region adjacent to the part in which the slot 362 is not formed may be adjusted. That is, in the discharge space 301 adjacent to the part in which the slot 362 is formed, the intensity of the electromagnetic field may be relatively strongly controlled, and in the discharge space 301 adjacent to the part in which the slot 362 is not formed, the intensity of the electromagnetic field may be relatively weakly controlled. Accordingly, it is possible to minimize a non-uniformity of the plasma generated in the discharge space 301 coming from structural limitations of the input terminal and the end terminal of the antenna 340. Accordingly, it is possible to improve the uniformity of the substrate treating process by allowing the plasma to uniformly affect the substrate W.

The cover member 360 according to an embodiment of the inventive concept described above has an octagonal shape as an example. However, this invention is not limited thereto, and the cover member 360 according to an embodiment may be formed by being modified into various polygonal shapes such as a square or a hexagon.

Furthermore, although the plasma generation unit 330 according to an embodiment of the inventive concept described above includes a shield member 370, the inventive concept is not limited thereto. For example, the shield member 370 may not be provided to the plasma generation unit 330 according to an embodiment.

Hereinafter, the cover member according to another embodiment of the inventive concept will be described in detail. The cover member according to an embodiment to be described below is provided in a similar manner to most of the cover members described above except for what is explained additionally. Accordingly, in order to avoid a duplication of content, descriptions of overlapping components will be omitted.

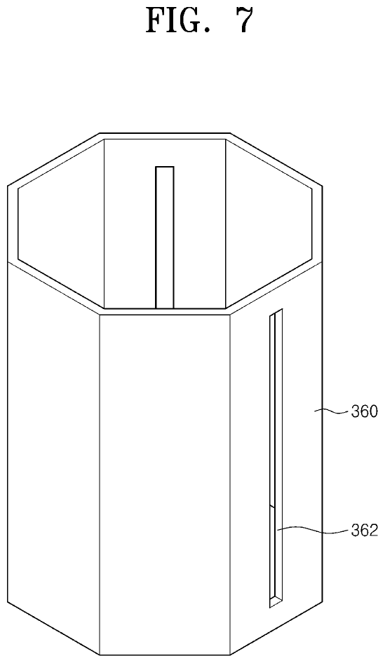

FIG. 7 is a perspective view of the cover member according to another embodiment of FIG. 2. A slot 362 may be formed in the cover member 360 according to an embodiment of the inventive concept. The slot 362 may be formed on a side surface of the cover member 360. The slot 362 may be formed between a top end and a bottom end of the cover member. A lengthwise direction of the slot 362 may be formed along a lengthwise direction of the cover member. A top end of the slot 362 may be formed at a height corresponding to the top end of the antenna 340. A bottom end of the slot 362 may be formed at a height corresponding to the bottom end of the antenna 340.

In addition, at least one slot 362 may be provided. For example, the plurality of slots 362 may be provided. The plurality of slots 362 may be disposed to be spaced apart from each other in the circumferential direction of the cover member 360. The plurality of slots 362 may be formed on a side surface of the cover member 360 corresponding to a region in which the intensity of the plasma formed in the discharge space 301 is relatively weak according to a movement of the plasma formed in the discharge space 301.

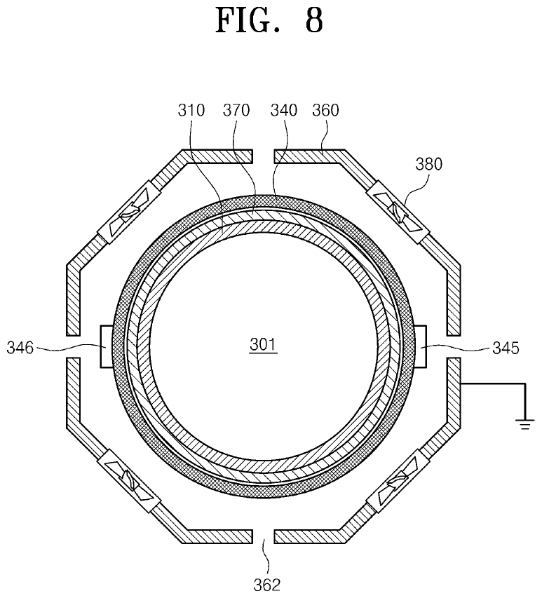

FIG. 8 through FIG. 10 are views schematically showing a top view of the cover member according to another embodiment of FIG. 2. Referring to FIG. 8, the cover member 360 according to an embodiment of the inventive concept may further include a fan unit 380. The fan unit 380 may be installed on the cover member 360. The fan unit 380 may be installed on a side surface of the cover member 360.

At least one fan unit 380 is provided. For example, a plurality of fan units 380 may be provided. The fan unit 380 is formed in an area that does not overlap the slot 362 formed in the cover member 360. For example, the fan unit 380 may not be installed on a side surface of the cover member 360 in which the slot 362 is formed. In addition, the slot 362 may not be installed on a side surface of the cover member 360 in which the fan unit 380 is installed.

The fan unit 380 may supply an airflow in a direction toward the outer wall of the plasma chamber 310. For example, the fan unit 380 may supply the airflow to an in-between space between the plasma chamber 310 and the cover member 360. The fan unit 380 may supply the airflow with an adjusted temperature and adjusted humidity to the in-between space.

The fan unit 380 may prevent a temperature of the in-between space from being excessively increased. The fan unit 380 may function as a cooler capable of preventing the in-between space from being excessively increased. For example, the fan unit 380 may cool a heat generated in the antenna 340 due to the high frequency power applied to the antenna 340. Accordingly, a heat transfer from the antenna 340 to the plasma chamber 310 may be minimized.

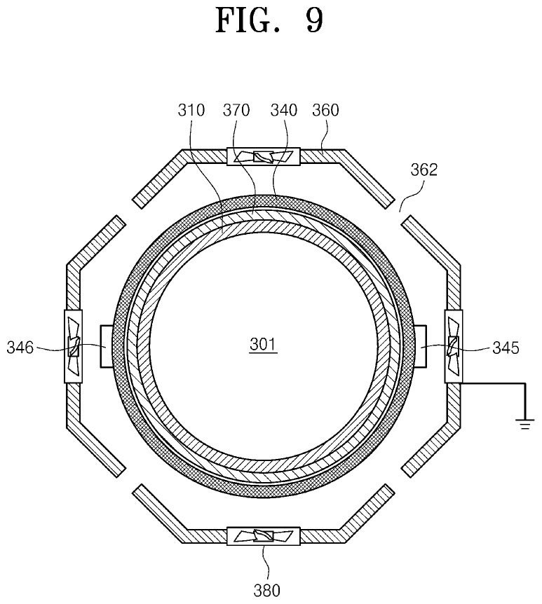

Referring to FIG. 9, the plurality of slots 362 may be formed at positions spaced apart from the power terminal 345 and the ground terminal 346 formed in the antenna 340. For example, slots 362 may not be formed on a virtual straight line connecting the power terminal 345 and the ground terminal 346. In addition, the plurality of fan units 380 may be installed on a side surface of the cover member 360 in which the slots 362 are not formed.

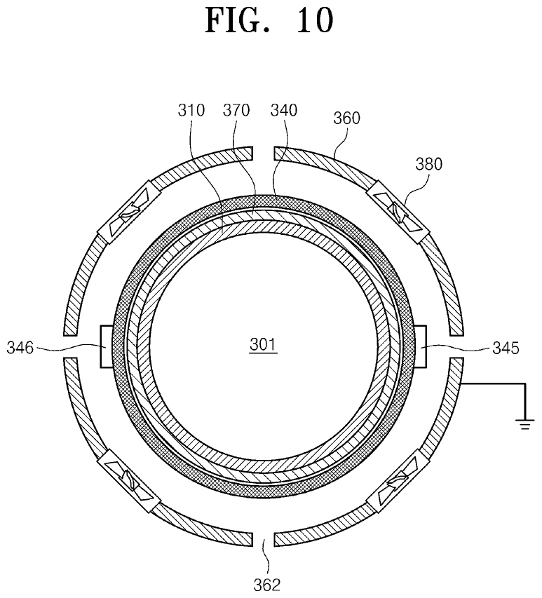

Referring to FIG. 10, the cover member 360 may be formed in a circular shape when viewed from above. For example, the cover member 360 may be provided in a substantially cylindrical shape. The cylindrical cover member 360 may be disposed outside the antenna 340 surrounding the outside of the plasma chamber 310.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A substrate treating apparatus comprising:
a process treating unit with a treating space for treating a substrate;
a plasma generation unit above the process treating unit and generating a plasma from a process gas;
the plasma generation unit comprising:
a plasma chamber having a discharge space formed therein;
an antenna surrounding an outside of the plasma chamber for flowing a high frequency current therethrough; and
a cover member surrounding an outside of the antenna,
wherein the cover member is grounded.

2. The substrate treating apparatus of claim 1, wherein the cover member has a slot extending from a top end of the cover member to a bottom end of the cover member.

3. The substrate treating apparatus of claim 2, wherein the slot is in a plurality, and the plurality of slots are apart from one another in a direction surrounding the antenna.

4. The substrate treating apparatus of claim 3, wherein a length of a lengthwise direction of the cover member is a same or longer than a length of a lengthwise direction of the antenna.

5. The substrate treating apparatus of claim 2, wherein the plasma generation unit further comprises a fan unit supplying an airflow to a space between the cover member and the plasma chamber.

6. The substrate treating apparatus of claim 5, wherein the fan unit is installed at the cover member, and in a position not overlapping with the slot.

7. The substrate treating apparatus of claim 1, wherein the antenna comprises a coil part surrounding an outside of the plasma chamber in a plurality of turns, and the coil part has a ground terminal to be grounded and a power terminal to be supplied with a high frequency power.

8. The substrate treating apparatus of claim 7, wherein the coil part comprises a plurality of coils, and each of the plurality of coils is independently connected to the power terminal and the ground terminal.

9. The substrate treating apparatus of claim 1, wherein the plasma generation unit further comprises a shield member positioned between the antenna and the plasma chamber, and grounded.

10. The substrate treating apparatus of claim 1, wherein the cover member has a disk shape when seen from above.

11. The substrate treating apparatus of claim 1, wherein the cover member has a polygonal shape when seen from above.

12. A plasma generation unit in a substrate treating apparatus using a plasma, the plasma generation unit comprising:
a chamber having a discharge space formed therein;
an antenna surrounding an outside of the chamber for flowing a high frequency current flowing therethrough; and
a cover member surrounding an outside of the antenna, and
wherein the cover member is grounded to generate an induced current in a opposite direction of the high frequency current.

13. The plasma generation unit of claim 12, wherein the cover member has a slot extending along a lengthwise direction of the shield member.

14. The plasma generation unit of claim 13, wherein the slot is in a plurality, and the plurality of slots are placed apart from one another in a direction surrounding the antenna.

15. The plasma generation unit of claim 12 further comprising a fan unit supplying an airflow to a space between the cover member and the chamber to cool the chamber.

16. The plasma generation unit of claim 12, wherein the antenna comprises a coil part surrounding the outside of the plasma chamber a plural number of times, and the coil part has a ground terminal to be grounded and a power terminal to be supplied with a high frequency power.

17. The plasma generation unit of claim 16, wherein the coil part comprises a plurality of coils, and each of the plurality of coils are independently connected to the power terminal and the ground terminal.

18. The plasma generation unit of claim 12, wherein a length of a lengthwise direction of the cover member is a same or longer than a length of a lengthwise direction of the antenna.

19. The plasma generation unit of claim 12, wherein the cover member has a polygonal shape when seen from above.

20. A substrate treating apparatus comprising:
a process treating unit for treating a substrate; and
a plasma generation unit positioned above the process treating unit for generating a plasma by exciting a gas, and
wherein the process treating unit comprises:
a housing having a treating space; and
a support unit in the treating space and supporting a substrate, and
wherein the plasma generation unit comprises:
a plasma chamber having a discharge space formed therein;
an antenna surrounding an outside of the plasma chamber for flowing a high frequency current flowing therethrough; and
a cover member surrounding an outside of the antenna and grounded, and
wherein the cover member has at least one slot extending from a top end of the cover member to a bottom end of the cover member.
